(19) United States
(12) Patent Application Publication
(10) Pub. No.: US 2017/0069811 A1
(43) Pub. Date: Mar. 9, 2017

(54) THERMOELECTRIC CONVERSION MATERIAL AND THERMOELECTRIC CONVERSION MODULE

(71) Applicant: HITACHI, LTD., Tokyo (JP)

(72) Inventors: Yosuke KUROSAKI, Tokyo (JP); Shin YABUUCHI, Tokyo (JP); Jun HAYAKAWA, Tokyo (JP)

(21) Appl. No.: 15/252,825

(22) Filed: Aug. 31, 2016

(30) Foreign Application Priority Data
Sep. 4, 2015 (JP) 2015-174977

(51) Int. Cl. H01L 35/04; H01L 35/18; H01L 35/22; H01L 35/16

(52) U.S. Cl. CPC H01L 35/04; H01L 35/16; H01L 35/18; H01L 35/22

(57) ABSTRACT

The present invention provides a thermoelectric conversion material that has low thermal conductivity and that is stable at a high temperature, and a thermoelectric conversion module using the same. The thermoelectric conversion material includes a granular base material including a semiconductor, a fine particle with a guest material distributed in the granular base material, and a binder with the guest material on a grain boundary of the granular base material. An amount of the binder is equal to or smaller than an amount of the fine particle, an amount of the granular base material is larger than a total amount of the binder and the fine particle, and the semiconductor and the guest material are in an isolated state not forming a compound by a eutectic reaction, a eutectoid reaction, a peritectic reaction, a peritectoid reaction, a monotectic reaction, or a segregation reaction.

### CLAIM OF PRIORITY

The present application claims priority from Japanese patent application JP 2015-174977 filed on Sep. 4, 2015, the content of which is hereby incorporated by reference into this application.

### BACKGROUND

The present invention relates to a thermoelectric conversion material and a thermoelectric conversion module using the same.

Recently, in view of solving social problems related to environmental pollution, mass consumption and disposal of energy, and resource depletion, there is increasing research and development for effective use of energy. Among others, approximately 60% of the energy is disposed as thermal energy in the course from the primary energy mainly including coal and petroleum to the final consumption in the industrial, commercial, and transportation divisions, and it is required to develop a technology of reusing the unused heat. Especially, power conversion from the exhaust heat is one of the largest requirements, and one technique for achieving it is a thermoelectric conversion system based on the Seebeck effect. The thermoelectric conversion system has high general versatility because it is scalable and useful without a turbine.

A thermoelectric conversion module constituting the thermoelectric conversion system converts heat into electric power by being brought close to a heat source and causing a temperature difference between its top and bottom. The thermoelectric conversion module is constituted by p-type and n-type thermoelectric conversion materials and an electrode and its thermoelectric conversion efficiency strongly depends on the thermoelectric conversion material. Thus, in order to improve the thermoelectric conversion efficiency, it is essential to improve the thermoelectric performance of the thermoelectric conversion material. The thermoelectric performance of the thermoelectric conversion material based on the Seebeck effect can be evaluated using a figure of merit ZT (non-dimensional) generally represented by Equation (1) below.

ZT=S²T/ρκ=S²T/ρ(κₑ+κₚₕ) (1)

In Equation (1) above, S represents a Seebeck coefficient, T represents an absolute temperature, ρ represents specific resistance, K represents thermal conductivity, κₑ represents thermal conductivity due to a carrier, and κₚₕ represents thermal conductivity due to a lattice. The larger ZT described above is, the higher the thermoelectric conversion efficiency of the thermoelectric conversion module is. Thus, it is necessary to manufacture a thermoelectric conversion material with large ZT.

It is evident from Equation (1) above that, to increase the figure of merit ZT of the thermoelectric conversion material, it suffices to increase the Seebeck coefficient S and decrease the specific resistance ρ and the thermal conductivity κ. In general, however, there is a tradeoff, such as the carrier number increasing as S and ρ decrease and κₑ increases, because the aforementioned parameters are correlated to each other. Therefore, a semiconductor is generally used as the thermoelectric conversion material. On the other hand, κₚₕ is in principle a parameter independent of the aforementioned parameter and which can be reduced by texture control using different materials as described below, and therefore it is effective in increasing ZT to decrease κₚₕ. Thus, to eliminate the aforementioned tradeoff for achieving the thermoelectric conversion system, material design for reducing κₚₕ and structural texture design of the material are required.

To reduce κₚₕ of the thermoelectric conversion material, while there is a method of reducing κₚₕ alone such as reducing the Debye temperature by replacing a heavy element, composite material formation with a different material is also known to be effective. Here, in the context of the composite material formation, the different material to be mixed with a base material is referred to as a guest material. For example, Japanese Unexamined Patent Application Publication No. 2015-056491 describes a method of reducing κₚₕ by forming a grain boundary phase containing an insulating material as the guest material on an interface of crystal grains of the base material. This method allows for greatly reducing κₚₕ due to the interfacial thermal resistance between the base material and the grain boundary phase. Moreover, Japanese Unexamined Patent Application Publication No. 2011-134989 describes another method of reducing κₚₕ by uniformly dispersing fine particles different from the base material as the guest material in the base material. This method allows for reducing κₚₕ by the fact that the guest fine particle acts as a scattering material for limiting a mean free path of phonons.

### SUMMARY

To reduce the thermal conductivity of the thermoelectric conversion material, as described above, the composite material formation with the different material using the interface between the base material and the guest material may be effective. Accordingly, the technologies described in Japanese Unexamined Patent Application Publication Nos. 2015-056491 and 2011-134989 are reviewed concerning problems to be solved for the future thermoelectric conversion material.

The thermoelectric conversion material is reviewed first for its performance. As a result, it is found in Japanese Unexamined Patent Application Publication No. 2015-056491 that the specific resistance ρ may greatly increase because the grain boundary phase is formed by the insulating material. It is also concerned that the effect of reducing the thermal conductivity κₚₕ by the lattice may be limited because there is no scattering material especially in the base material. As for Japanese Unexamined Patent Application Publication No. 2011-134989, it is concerned that the effect of reducing the thermal conductivity κₚₕ may be limited because there is only a small contribution by the interfacial thermal resistance between the base material and the guest fine particles.

Next, the technologies are reviewed in terms of a manufacturing process and a use temperature. To combine the increase in Seebeck coefficient S due to the improved crystalline property of the base material and the reduction in κₚₕ due to the grain growth inhibition of the base material in manufacturing a composite material, a short-time thermal treatment at a high temperature may be effective. Moreover, because a thermoelectric conversion module using the thermoelectric material manufactured is used at the high temperature, a structure stable in the high-temperature use is required. However, in any of the aforementioned methods, because the guest material has a microstructure to sufficiently scatter phonons and has a large surface area, it is highly reactive to the base material. Hence, if the thermoelectric conversion material is thermally treated at a high temperature or the thermoelectric conversion module is used at a high temperature, the guest material may be dispersed into the base material and an interfacial structure between the base material and the guest material may be collapsed, which may reduce the effect of reducing κₚₕ. As a result, the performance of the thermoelectric conversion material manufactured is degraded and the conversion efficiency of the thermoelectric conversion module is degraded at the same time. It is thus found that there is another problem in manufacturing a composite material that achieves low thermal conductivity and that is stable at a high temperature.

It is an object of the present invention to provide a thermoelectric conversion material that has low thermal conductivity and that is stable at a high temperature despite its composite material structure, and a thermoelectric conversion module using the same.

An embodiment for achieving the aforementioned object is a thermoelectric conversion material including: a granular base material including a semiconductor; a fine particle with a guest material dispersed in the granular base material; and a binder with the guest material on a grain boundary of the granular base material,

wherein an amount of the binder is equal to or smaller than an amount of the fine particle,

an amount of the granular base material is larger than a total amount of the binder and the fine particle, and

the semiconductor and the guest material are in an isolated state not forming a compound by a eutectic reaction, a eutectoid reaction, a peritectic reaction, a peritectoid reaction, a monotectic reaction, or a segregation reaction.

Another embodiment is a thermoelectric conversion material including: a granular base material including a semiconductor made of a silicon compound, a chalcogenide compound, or a skutterudite compound; a fine particle with a guest material dispersed in the granular base material; and a binder with the guest material on a grain boundary of the granular base material,

wherein the semiconductor and the guest material are in an isolated state not forming a compound by a eutectic reaction, a eutectoid reaction, a peritectic reaction, a peritectoid reaction, a monotectic reaction, or a segregation reaction.

Another embodiment is a thermoelectric conversion material including: a granular base material including a semiconductor made of a silicon compound, a chalcogenide compound, or a skutterudite compound; a fine particle with a guest material dispersed in the granular base material; and a binder with the guest material on a grain boundary of the granular base material,

wherein an amount of the binder is equal to or smaller than an amount of the fine particle,

an amount of the granular base material is larger than a total amount of the binder and the fine particle, and

the semiconductor and the guest material are in an isolated state not forming a compound by a eutectic reaction, a eutectoid reaction, a peritectic reaction, a peritectoid reaction, a monotectic reaction, or a segregation reaction.

Another embodiment is a thermoelectric conversion module including multiple thermoelectric conversion units including any one of the thermoelectric conversion materials described above and electrodes provided at both ends of the thermoelectric conversion material.

According to an aspect of the present invention, it is possible to provide a thermoelectric conversion material that has low thermal conductivity and that is stable at a high temperature despite its composite material structure, and a thermoelectric conversion module using the same.

### BRIEF DESCRIPTION OF THE DRAWINGS

FIG. 1 is a schematic cross-sectional view illustrating a structure of a thermoelectric conversion material according to a first embodiment of the present invention;

FIG. 2A is a schematic plan view showing a main part of a thermoelectric conversion module constituted by the thermoelectric conversion material (thin film material) according to the first embodiment of the present invention;

FIG. 2B is a perspective view of the thermoelectric conversion module according to the first embodiment of the present invention;

FIG. 3 is a cross-sectional HAADF-STEM image of a thermoelectric conversion material thin film with Si/Mn composition ratio of 1.7 (first comparative example);

FIG. 4 is a cross-sectional HAADF-STEM image of a thermoelectric conversion material thin film with Si/Mn composition ratio of 2.8 (second comparative example);

FIG. 5 is a cross-sectional HAADF-STEM image of a thermoelectric conversion material thin film with Si/Mn composition ratio of 2.2 (first embodiment);

FIG. 6 is a graph showing Si/Mn composition ratio dependencies of thermal conductivity and figure of merit ZT of the thermoelectric conversion material (first and second comparative examples, first embodiment) at a room temperature;

FIG. 7A is a schematic cross-sectional view showing a main part of a thermoelectric conversion module constituted by a thermoelectric conversion material (bulk material) according to a second embodiment of the present invention;

FIG. 7B is a perspective view of the thermoelectric conversion module according to the second embodiment of the present invention;

FIG. 8 is a schematic view of a one-dimensional model approximation for evaluating thermoelectric conversion performance of the second embodiment of the present invention;

FIG. 9 is a correlation diagram between quantity ratio α of a binder and a particle and the room temperature ZT in the thermoelectric conversion material (bulk material) according to the second embodiment of the present invention;

FIG. 10 is a correlation diagram between a quantity ratio β of a guest material and a base material and the room temperature ZT in the thermoelectric conversion material (bulk material) according to the second embodiment of the present invention;

FIG. 11 is a schematic cross-sectional view showing a main part of a thermoelectric conversion module constituted by a thermoelectric conversion material (bulk material) according to a third embodiment of the present invention;

FIG. 12 is a correlation diagram between the quantity ratio α of the binder and the particle and the room temperature ZT in the thermoelectric conversion material (bulk material) according to the third embodiment of the present invention;

FIG. 13 is a correlation diagram between the quantity ratio β of the guest material and the base material and the room temperature ZT in the thermoelectric conversion material (bulk material) according to the third embodiment of the present invention;

FIG. 14 is a schematic cross-sectional view showing a main part of a thermoelectric conversion module constituted by a thermoelectric conversion material (thin film material) according to a fourth embodiment of the present invention;

FIG. 15 is a correlation diagram between the quantity ratio α of the binder and the fine particle and the room temperature ZT in the thermoelectric conversion material (bulk material) according to the fourth embodiment of the present invention; and

FIG. 16 is a correlation diagram between the quantity ratio β of the guest material and the base material and the room temperature ZT in the thermoelectric conversion material (bulk material) according to the fourth embodiment of the present invention.

### DETAILED DESCRIPTION

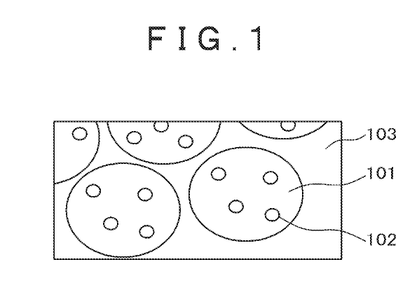

After observing the aforementioned problems, the inventors have dispersed fine particles including a guest material being a thermoelectric conversion material in a base material also being a thermoelectric conversion material, thereby manufactured a binder including the guest material on a grain boundary of the base material. The fine particle herein refers to a particle present in the base material, which is specified to have a grain size smaller than that of the base material. As a result, it has been found that an amount of the guest material including the fine particles and the binder should be smaller than the amount of the base material and the amount of the binder should preferably be smaller than the amount of the fine particle, and that the base material should be the semiconductor that is the thermoelectric conversion material and the guest material should be constituted by a material existing in an isolated state not forming a compound with each other by a eutectic reaction, a eutectoid reaction, a peritectic reaction, a peritectoid reaction, a monotectic reaction, or a segregation reaction. FIG. 1 shows a schematic cross-sectional view of the thermoelectric conversion material. 101 denotes the base material, 102 denotes the guest material fine particle, and 103 denotes the guest material binder. The binder present between the base materials is formed with the purpose of reducing thermal conductivity of a composite material by interfacial thermal resistance between the base material and the binder, and it is needless to say that the effect of reducing the thermal conductivity can be obtained even if a part of the binder is missing and base materials are bonded to each other or if the binder has uneven thickness. A ratio of the base material to the guest material can be identified by evaluating a composition of the whole sample by the ICP (Inductive Couple Plasma) analysis, for example, and evaluating the ratio of Mn to Si. The amount of the fine particles and the amount of the binder can be identified by a depthwise distribution evaluation using the RBS (Rutherford Back Scattering) analysis or the SIMS (Secondary Ion Mass Spectroscopy) analysis, for example, and an in-plane distribution evaluation using the EDX (Energy Dispersive X-ray Spectroscopy) analysis. These amounts can also be identified by observing a real image of the sample using the SEM (Scanning Electron Microscopy) or the TEM (Transmission Electron Microscopy).

According to the thermoelectric conversion material having the composite material structure described above, it is possible to achieve sufficiently low thermal conductivity. Because both the base material and the guest material are made of semiconductors that are thermoelectric conversion materials, the thermoelectric performance cannot be substantially reduced due to the quantity ratio. Moreover, because the base material and the guest material do not form a compound in principle, it is possible to perform a thermal treatment process at a high temperature and to use the thermoelectric conversion module using the thermoelectric conversion material with the composite material structure at a high temperature.

Embodiments of the present invention will be described below with reference to drawings.

### First Embodiment

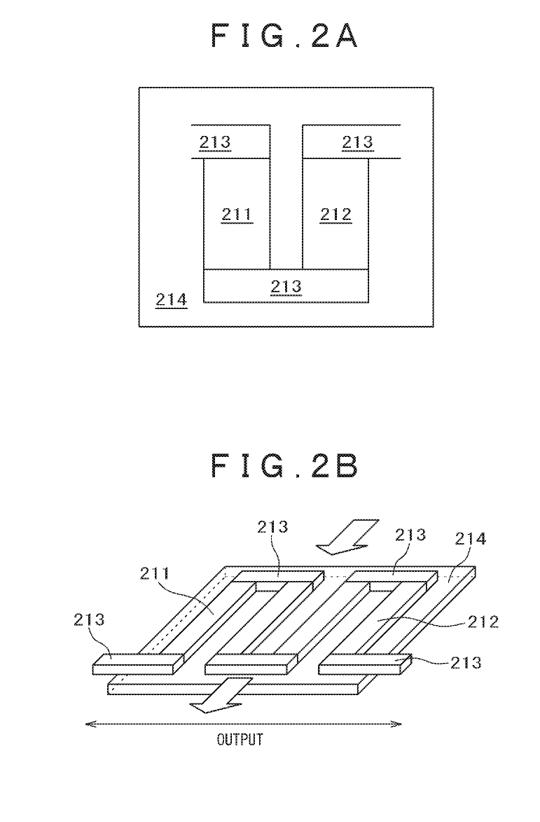

A first embodiment of the present invention will be described with reference to FIGS. 2A to 6. FIG. 2A shows a schematic cross-sectional view of a main part (thermoelectric conversion unit) of a thermoelectric conversion module according to this embodiment. FIG. 2B shows a schematic perspective view of the thermoelectric conversion module according to this embodiment. The thermoelectric conversion module is constituted in a form of a thin film, in which a plurality of thermoelectric conversion units constituted by a p-type thermoelectric conversion material 211, an n-type thermoelectric conversion material 212, and an electrode 213 are arranged, and the p-type thermoelectric conversion material 211 and the n-type thermoelectric conversion material 212 are alternately connected to each other via the electrode 213. A n-type conversion unit including the thermoelectric conversion material and the electrode is formed on a lower substrate 214. By providing a temperature difference between both ends of the thermoelectric conversion module in an in-plane direction of the thin film (indicated by an arrow in FIG. 2B), the p-type thermoelectric conversion material 211 and the n-type thermoelectric conversion material 212 can generate electric power, thus the electric power can be obtained from the temperature difference via the electrode 213. The number of the thermoelectric conversion units in the thermoelectric conversion module can be selected depending on its application.

In this embodiment, the thermoelectric conversion performance of the thermoelectric conversion module is improved by incorporating the thermoelectric conversion material with high thermoelectric conversion performance. Specifically, the p-type thermoelectric conversion material 211 and the n-type thermoelectric conversion material 212 are formed of the thermoelectric conversion material in which Si fine particles as the guest material are dispersed in manganese silicide (MnSi_{1.7}) as the base material and the Si binder is present on the grain boundary of MnSi_{1.7}. In the n-type thermoelectric conversion material 212, a part of MnSi_{1.7} is replaced by Fe to make a carrier n-type. An amount of the base material MnSi_{1.7} is larger than an amount of the guest material Si containing the fine particles and the binder, and also an amount of the binder is equal to or smaller than an amount of the fine particles.

Because the combination of the base material and the guest material is a combination of a eutectic reaction even when they are, for example, Mg₂Si and Si, it presents the same effect as the combination of MnSi_{1.7} and Si. Accordingly, the base material is the semiconductor made of a silicon compound, which may be the silicon compound containing at least one type of element from among transition metals (Ti, V, Cr, Mn, Fe, Co, Ni, Cu, Zr, Nb, Mo, La, Ta, W) or alkali metals and alkali earth metals (Li, Na, K, Rb, Mg, Ca, Sr, Ba). The guest material may be a material that does not form a compound with the base material by the eutectic reaction, the eutectoid reaction, the peritectic reaction, the peritectoid reaction, the monotectic reaction, or the segregation reaction to confirm a similar effect. In the base material and the guest material, a part thereof may be replaced by an element other than the constituent element to improve a figure of merit.

The reason why the conversion performance of the thermoelectric conversion material used in this embodiment can be improved is described below. In this embodiment, the magnetron sputtering is used for the thin film formation, and the thermoelectric conversion material thin film is formed by thermal treatment at 600° C. The thin film is formed on a silicon substrate coated by a thermally oxidized film.

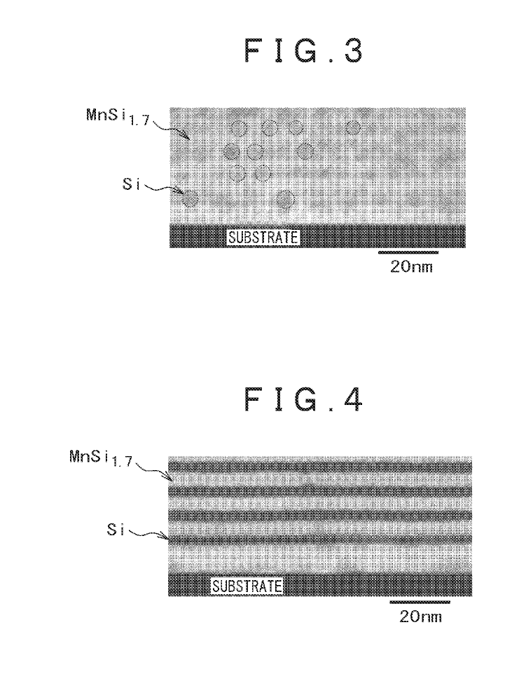

FIG. 3 shows a cross-sectional HAADF-STEM image (High-angle Annular Dark Field Scanning TEM) of a thin film with Si/Mn composition ratio of 1.7. In an HAADF-STEM image, a heavy element is displayed bright and a light element is displayed dark. Combined with the result of the EDX analysis, the bright field contains MnSi_{1.7}, the dark field contains Si, and Si fine particles are dispersed in MnSi_{1.7} (first comparative example).

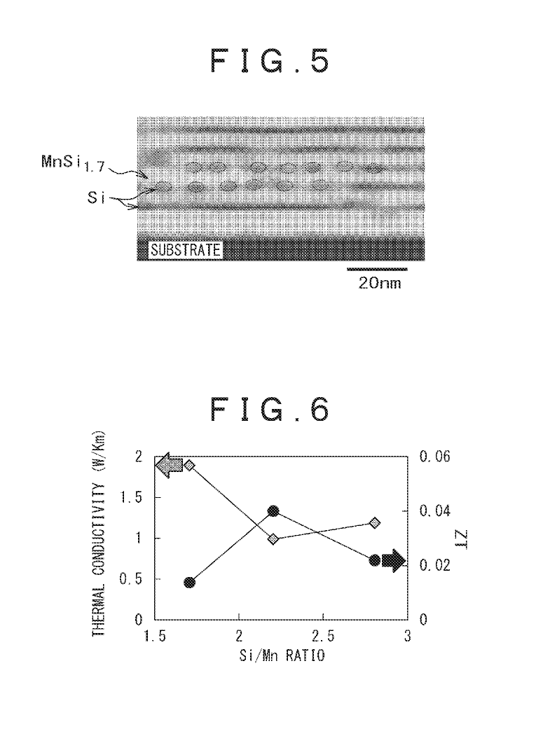

FIGS. 4 and 5 show cross-sectional HAADF-STEM images of thin films with the Si/Mn composition ratios of 2.8 and 2.2, respectively. In both cases, as in the case of the Si/Mn composition ratio of 1.7, the bright field contains MnSi_{1.7} and the dark field contains Si. In the thin film with the Si/Mn composition ratios of 2.8 (FIG. 4), there is an Si binder formed between MnSi_{1.7} layers (second comparative example). On the other hand, in the thin film with the Si/Mn composition ratios of 2.2 (FIG. 5), in addition to the Si binder formed between the MnSi_{1.7} layers, Si fine particles are distributed in MnSi_{1.7} by the thermal treatment (present embodiment).

FIG. 6 shows Si/Mn composition ratio dependencies of thermal conductivity and ZT at a room temperature. The thermal conductivity is the lowest in the thin film with the Si/Mn composition ratio of 2.2 and ZT is the highest in the thin film with the Si/Mn composition ratio of 2.2. This can lead to an observation that, in the thin film with the Si/Mn composition ratio of 2.2, the thermal conductivity of the MnSi_{1.7} layer is reduced due to the presence of the Si fine particles in the MnSi_{1.7} and the thermal conductivity is substantially reduced at the same time by the interfacial thermal resistance between the interfacial thermal resistance layer and the Si binder, resulting in improvement of ZT. Because the thin film has the Si/Mn composition ratio of 2.2 and an amount of MnSi_{1.7} with higher thermoelectric performance more than an amount of Si with lower thermoelectric performance, it prevents degradation of the thermoelectric performance involved in the composite material formation.

Moreover, because of lower thermoelectric performance, it is preferred that the Si binder is formed as thin as possible and the remainder is present in MnSi_{1.7} in the form of the Si fine particles as a scattering source of phonons. In fact, in the thin film with the Si/Mn composition ratios of 2.8 shown in the second comparative example, because the Si binder has approximately the same thickness as the MnSi_{1.7} layer, its specific resistance is in the order of two times that of the thin film with the Si/Mn composition ratios of 2.2, resulting in substantial reduction in ZT.

Furthermore, because such materials that do not form any compound with each other are selected as the base material and the guest material, it is possible to effectively reduce the thermal conductivity without collapsing interface structures of the base material and the guest material. At the same time, even if the thermoelectric conversion unit manufactured according to this embodiment is used at a high temperature, the interface structures are not collapsed, allowing for retaining the thermoelectric performance of the thermoelectric conversion material.

For the thermoelectric conversion material used in this embodiment, the base material and the guest material are selected to have high ZT and also the texture structure of the base material and the guest material are controlled accordingly. However, the manufacturing method is not limited to the above, and the thermoelectric conversion material may be manufactured by other thin film manufacturing methods such as, for example, MBE (Molecular Beam Epitaxy), PLD (Pulse Laser Deposition), and CVD (Chemical Vapor Deposition). Moreover, because such materials that do not form any compound with each other are selected as the base material and the guest material, the thermal treatment temperature is not limited to 600° C. used in this embodiment, but it is possible to optimize the thermoelectric performance by specifying an optimal thermal treatment temperature according to its material and texture structure.

As described above, according to this embodiment, it is possible to provide a thermoelectric conversion material that has low thermal conductivity and that is stable at a high temperature despite its composite material structure, and a thermoelectric conversion module using the same.

### Second Embodiment

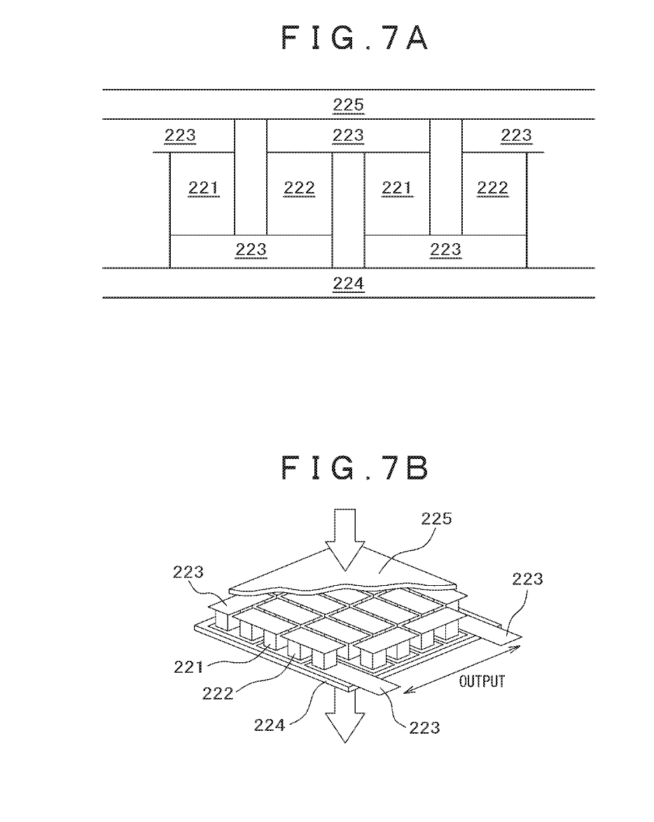

A second embodiment of the present invention will be described with reference to FIGS. 7A, 7B, and 8 to 10. It is noted that what is described in the first embodiment but not in this embodiment may be applied to this embodiment unless the circumstances are exceptional.

FIG. 7A shows a schematic cross-sectional view of a main part of a thermoelectric conversion module according to this embodiment. FIG. 7B shows a schematic perspective view of the thermoelectric conversion module according to this embodiment. The thermoelectric conversion module includes a plurality of thermoelectric conversion units constituted by a p-type thermoelectric conversion material 221, an n-type thermoelectric conversion material 222, and an electrode 223, and the p-type thermoelectric conversion material 221 and the n-type thermoelectric conversion material 222 are alternately connected to each other via the electrode 223. A n-type conversion unit including the thermoelectric conversion material and the electrode is sandwiched by a lower substrate 224 and an upper substrate 225. By providing a temperature difference between both ends of the thermoelectric conversion module constituted by the lower substrate 224, the upper substrate 225, and the conversion unit sandwiched by these substrates (in a direction of a downward arrow in FIG. 7B), the p-type thermoelectric conversion material 221 and the n-type thermoelectric conversion material 222 can generate electric power due to the Seebeck effect, thus the electric power can be obtained from the temperature difference via the electrode 223.

In this embodiment, the thermoelectric conversion performance of the thermoelectric conversion module is improved by incorporating the thermoelectric conversion material with high thermoelectric conversion performance. Specifically, the p-type thermoelectric conversion material 221 and the n-type thermoelectric conversion material 222 are formed of the thermoelectric conversion material in which Si fine particles as the guest material are dispersed in magnesium silicide (Mg₂Si) as the base material and the Si binder is present on the grain boundary of Mg₂Si. In the p-type thermoelectric conversion material 221, apart of Mg₂Si is replaced by Ag to make a carrier p-type. An amount of the base material Mg₂Si is larger than an amount of the guest material Si containing the fine particles and the binder, and also an amount of the binder is smaller than an amount of the fine particles. The base material is the semiconductor made of a silicon compound, which may be the silicon compound containing at least one type of element from among transition metals (Ti, V, Cr, Mn, Fe, Co, Ni, Cu, Zr, Nb, Mo, La, Ta, W) or alkali metals and alkali earth metals (Li, Na, K, Rb, Mg, Ca, Sr, Ba). The guest material may be a material that does not form a compound with the base material by the eutectic reaction, the eutectoid reaction, the peritectic reaction, the peritectoid reaction, the monotectic reaction, or the segregation reaction, thereby obtaining the similar effect. In the base material and the guest material, a part thereof may be replaced by an element other than the constituent element to improve a figure of merit.

Now, each of the p-type thermoelectric conversion material 221 and the n-type thermoelectric conversion material 222 is made into fine particles by the mechanical ironing and then sintered for a short time by the spark plasma sintering. By employing this method, it is possible to make the particle diameter of the base material Mg₂Si of the sintered body to 1 μm or even smaller, resulting in reduction in the thermal conductivity κ. The sintering temperature and the sintering time are 600° C. and 60 seconds, respectively. The electrode 223 is made of Cu, and the lower substrate 224 and the upper substrate 225 are made of AlN. Because such materials that do not form any compound with each other are selected as the base material and the guest material, the thermal treatment temperature is not limited to 600° C. used in this embodiment, but it is possible to optimize the thermoelectric performance by specifying an optimal thermal treatment temperature according to its material and texture structure. Also, the thermal treatment time is not limited to 60 seconds as in this embodiment, but it is possible to optimize the thermoelectric performance by specifying an optimal thermal treatment time according to its material and texture structure.

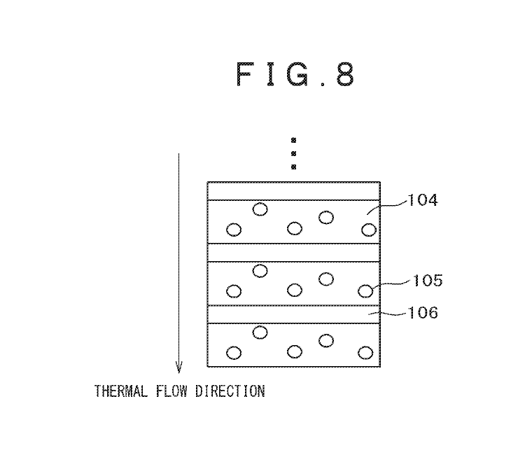

The thermoelectric conversion performance of the thermoelectric conversion material used in this embodiment is approximated to a one-dimensional model shown in FIG. 8 to perform an evaluation. 104 denotes the base material, 105 denotes the guest material fine particle, and 106 denotes the guest material binder.

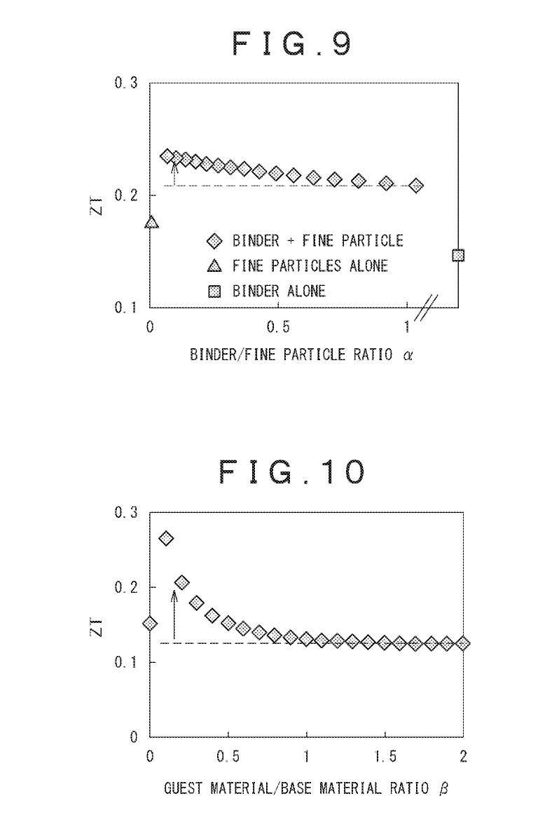

FIG. 9 shows a variation of the figure of merit ZT of Si used as the guest material at the room temperature when the ratio α of the binder amount to the fine particle amount changes (where ratio of guest material/base material β=0.1). ZT increases when α is 1 or smaller (binder amount less than fine particle amount). This indicates that Si being the guest material is preferably present as a scattering source of phonons by forming fine particles without forming a layer as the binder as far as possible. As a result, the amount of the binder present between the base materials is preferably equal to or smaller than the amount of the fine particles present in the base material. Moreover, ZT of the thermoelectric conversion material that contains both the binder and the fine particles is higher than ZT of the sample that contains the fine particles alone (corresponding to α=0) and also higher than ZT of the sample that contains the binder alone (corresponding to α=∞). From this result, it can be contemplated that the reduction in the thermal conductivity may be greater when both the binder and the fine particles are present, which results in the high ZT.

FIG. 10 shows a variation of ZT at the room temperature when β, the quantity ratio of Si being the guest material to Mg₂Si being the base material, changes (where α=0.5). When β is smaller than 1 (the amount of the base material is larger than the amount of the guest material), ZT markedly increases. Due to the effect of the composite material formation, ZT markedly increases more than the base material Mg2Si alone (corresponding to β=0).

As described above, this embodiment can achieve the same effect as the first embodiment. It is also possible to provide the thermoelectric conversion material made of the sintered body.

### Third Embodiment

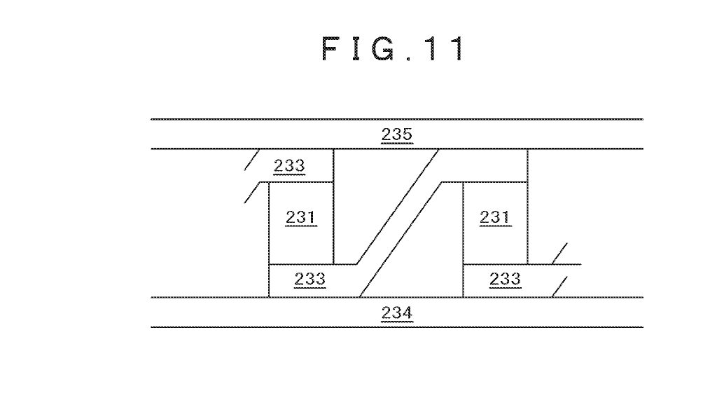

A third embodiment of the present invention will be described with reference to FIGS. 11 to 13. It is noted that what is described in the first or second embodiment but not in this embodiment may be applied to this embodiment unless the circumstances are exceptional.

FIG. 11 shows a schematic cross-sectional view of a main part of a thermoelectric conversion module according to this embodiment. The thermoelectric conversion module includes a plurality of thermoelectric conversion units constituted by a thermoelectric conversion material 231 and an electrode 233, and the thermoelectric conversion material 231 is constituted by either one of p-type or n-type. The uni-leg conversion unit including the thermoelectric conversion material and the electrode descried above is sandwiched by a lower substrate 234 and an upper substrate 235.

In this embodiment, the thermoelectric conversion performance of the thermoelectric conversion unit is improved by incorporating the thermoelectric conversion material with high thermoelectric conversion performance. Specifically, the thermoelectric conversion material 231 is formed of the thermoelectric conversion material in which Te fine particles as the guest material are dispersed in chalcogenide (PbTe) as the base material and a Te binder is present on the grain boundary of PbTe. An amount of the base material PbTe is larger than an amount of the guest material Te containing the fine particles and the binder, and also an amount of the binder is equal to or smaller than an amount of the fine particles. The base material may be a semiconductor of chalcogenide compound containing at least one type of element from among the group 16 elements (S, Se, and Te). The guest material may be a material that does not form a compound with the base material by the eutectic reaction, the eutectoid reaction, the peritectic reaction, the peritectoid reaction, the monotectic reaction, or the segregation reaction to confirm a similar effect. In the base material and the guest material, a part thereof may be replaced by an element other than the constituent element to improve a figure of merit. It is also possible to apply the base material and the guest material described in this embodiment to the n-type conversion unit described in the first and second embodiments.

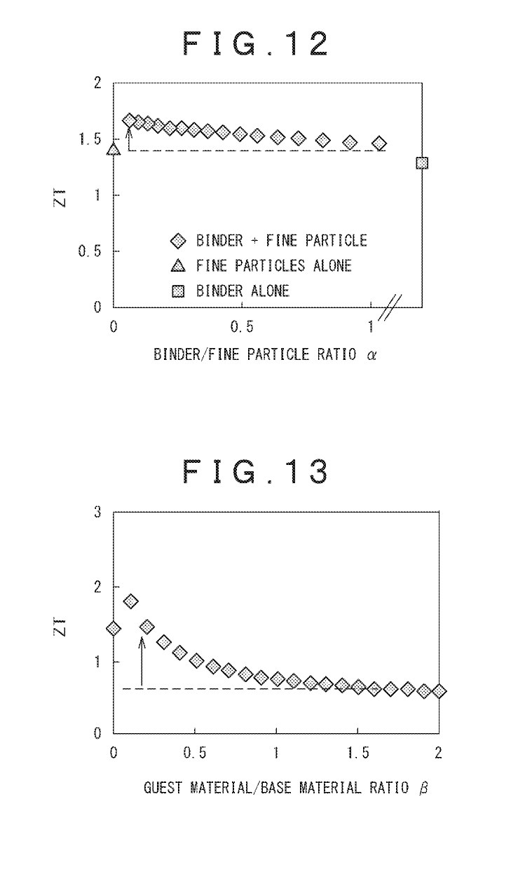

FIG. 12 shows a variation of ZT at a room temperature when the ratio α of the binder amount to the fine particle amount changes (where ratio of guest material/base material β=0.1), regarding Te used as the guest material. FIG. 13 shows a variation of ZT at the room temperature when β, the quantity ratio of Te being the guest material to PbTe being the base material, changes (where α=0.5). Both ZT variations are the same as in the second embodiment, which indicates that ZT improves due to the composite material formation.

As described above, according to this embodiment, it is possible to provide a thermoelectric conversion material that has low thermal conductivity and that is stable at a high temperature despite its composite material structure, and a thermoelectric conversion module using the same.

### Fourth Embodiment

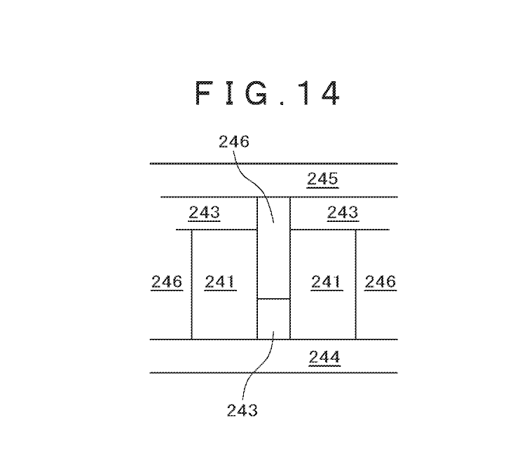

A fourth embodiment of the present invention will be described with reference to FIGS. 14 to 16. It is noted that what is described in any one of the first to third embodiments but not in this embodiment may be applied to this embodiment unless the circumstances are exceptional.

FIG. 14 shows a schematic cross-sectional view of a main part of a thermoelectric conversion module according to this embodiment. The thermoelectric conversion module is constituted in a form of a thin film constituted by a thermoelectric conversion material 241, an electrode 243, and an interlayer insulating film 246, and the uni-leg conversion unit is sandwiched between a lower substrate 244 and an upper substrate 245.

In this embodiment, the thermoelectric conversion performance of the thermoelectric conversion unit is improved by incorporating the thermoelectric conversion material with high thermoelectric conversion performance. Specifically, the thermoelectric conversion material 241 is formed of the thermoelectric conversion material in which Sb fine particles as the guest material are dispersed in skutterudite (CoSb₃) as the base material and an Sb binder is present on the grain boundary of CoSb₃. An amount of the base material CoSb₃ is larger than an amount of the guest material Sb containing the fine particles and the binder, and also an amount of the binder is equal to or smaller than an amount of the fine particles. The base material may be a semiconductor of skutterudite compound containing at least one type of element from among the group 15 elements (P, As, Sb). The guest material may be a material that does not form a compound with the base material by the eutectic reaction, the eutectoid reaction, the peritectic reaction, the peritectoid reaction, the monotectic reaction, or the segregation reaction to confirm a similar effect. In the base material and the guest material, a part thereof may be replaced by an element other than the constituent element to improve a figure of merit.

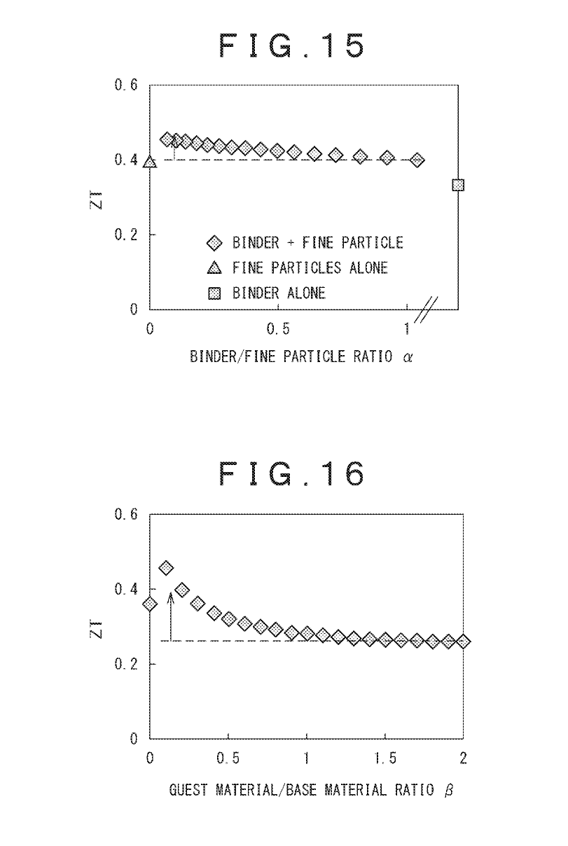

FIG. 15 shows a variation of ZT of Sb used as the guest material at a room temperature when the ratio α of the binder amount to the fine particle amount changes (where ratio of guest material/base material β=0.1). FIG. 16 shows a variation of ZT at the room temperature when β, the quantity ratio of Sb being the guest material to PbTe being the base material, changes (where α=0.5). Both ZT variations are the same as in the second embodiment, which indicates that ZT improves due to the composite material formation.

As described above, according to this embodiment, it is possible to provide a thermoelectric conversion material that has low thermal conductivity and that is stable at a high temperature despite its composite material structure, and a thermoelectric conversion module using the same.

It should be noted that the present invention is not limited to the above embodiments but includes various modifications. For example, the above embodiments are intended to describe the present invention in detail for comprehensive illustration and not to limit the present invention to what includes all the elements described above. It is possible to replace a part of a configuration in one embodiment with the configuration in another embodiment, and also to add the configuration of one embodiment to the configuration of another embodiment. Apart of the configuration in each embodiment can be added to, deleted, or replaced by another configuration.

What is claimed is:

1. A thermoelectric conversion material comprising:
a granular base material including a semiconductor;
a fine particle with a guest material dispersed in the granular base material; and
a binder with the guest material on a grain boundary of the granular base material,
wherein an amount of the binder is equal to or smaller than an amount of the fine particle,
an amount of the granular base material is larger than a total amount of the binder and the fine particle, and
the semiconductor and the guest material are in an isolated state not forming a compound by a eutectic reaction, a eutectoid reaction, a peritectic reaction, a peritectoid reaction, a monotectic reaction, or a segregation reaction.

2. A thermoelectric conversion material comprising:
a granular base material including a semiconductor made of a silicon compound, a chalcogenide compound, or a skutterudite compound;
a fine particle with a guest material dispersed in the granular base material; and
a binder with the guest material on a grain boundary of the granular base material,
wherein the semiconductor and the guest material are in an isolated state not forming a compound by a eutectic reaction, a eutectoid reaction, a peritectic reaction, a peritectoid reaction, a monotectic reaction, or a segregation reaction.

3. The thermoelectric conversion material according to claim 2,
wherein the base material is a semiconductor made of the silicon compound, and
the silicon compound contains at least one type of element from among transition metals including Ti, V, Cr, Mn, Fe, Co, Ni, Cu, Zr, Nb, Mo, La, Ta, and W, or alkali metals and alkali earth metals including Li, Na, K, Rb, Mg, Ca, Sr, and Ba.

4. The thermoelectric conversion material according to claim 2,
wherein the base material is a semiconductor made of the chalcogenide compound, and
the chalcogenide compound contains at least one type of element from among the group 16 elements including S, Se, and Te.

5. The thermoelectric conversion material according to claim 2,
wherein the base material is a semiconductor made of the skutterudite compound, and
the skutterudite compound contains at least one type of element from among the group 15 elements including P, As, and Sb.

6. A thermoelectric conversion material comprising:
a granular base material including a semiconductor made of a silicon compound, a chalcogenide compound, or a skutterudite compound;
a fine particle with a guest material dispersed in the granular base material; and
a binder with the guest material on a grain boundary of the granular base material,
wherein an amount of the binder is equal to or smaller than an amount of the fine particle,
an amount of the granular base material is larger than a total amount of the binder and the fine particle, and
the semiconductor and the guest material are in an isolated state not forming a compound by a eutectic reaction, a eutectoid reaction, a peritectic reaction, a peritectoid reaction, a monotectic reaction, or a segregation reaction.

7. The thermoelectric conversion material according to claim 6,
wherein the base material is a semiconductor made of the silicon compound, and
the silicon compound contains at least one type of element from among transition metals including Ti, V, Cr, Mn, Fe, Co, Ni, Cu, Zr, Nb, Mo, La, Ta, and W, or alkali metals and alkali earth metals including Li, Na, K, Rb, Mg, Ca, Sr, and Ba.

8. The thermoelectric conversion material according to claim 6,
wherein the base material is a semiconductor made of the chalcogenide compound, and
the chalcogenide compound contains at least one type of element from among the group 16 elements including S, Se, and Te.

9. The thermoelectric conversion material according to claim 6,
wherein the base material is a semiconductor made of the skutterudite compound, and
the skutterudite compound contains at least one type of element from among the group 15 elements including P, As, and Sb.

10. A thermoelectric conversion module comprising a plurality of thermoelectric conversion units including the thermoelectric conversion material according to claim 1 and electrodes provided at both ends of the thermoelectric conversion material.

11. The thermoelectric conversion module according to claim 10,
wherein the thermoelectric conversion unit is of a n-type.

12. The thermoelectric conversion module according to claim 10,
wherein the thermoelectric conversion unit is of a uni-leg type.

13. A thermoelectric conversion module comprising a plurality of thermoelectric conversion units including the thermoelectric conversion material according to claim 2 and electrodes provided at both ends of the thermoelectric conversion material.

14. A thermoelectric conversion module comprising a plurality of thermoelectric conversion units including the thermoelectric conversion material according to claim 6 and electrodes provided at both ends of the thermoelectric conversion material.
